(19) United States
(12) Patent Application Publication
(10) Pub. No.: US 2026/0353866 A1
(43) Pub. Date: Nov. 5, 2026

(54) OPTOELECTRONIC DEVICE AND METHOD FOR OPERATING THE SAME

(71) Applicant: ams-OSRAM Intermational GmbH, Regensburg (DE)

(72) Inventors: Alvaro Gomez-Iglesias, Regensburg (DE); Michael Binder, Barbing (DE); Hans-Jürgen Lugauer, Sinzing (DE)

(21) Appl. No.: 19/487,368

(22) PCT Filed: May 23, 2024
(86) PCT No.: PCT/EP2024/064310

§ 371 Date: Nov. 24, 2025

(30) Foreign Application Priority Data
May 24, 2023 (DE) 102023113574.0

(51) Int. Cl. H10H 20/812; H10H 20/01; H10H 20/824; H10H 20/84

(52) U.S. Cl. CPC H10H 20/812; H10H 20/0133; H10H 20/034; H10H 20/824; H10H 20/84

(57) ABSTRACT

In an embodiment an optoelectronic device includes a mesa etched layer stack including a first layer doped with a first doping type, a second layer doped with a second doping type, and an active layer arranged between the first doped layer and the second doped layer, wherein mesa etched sidewalls at or in an immediate vicinity of the active layer include a plurality of surface states configured for facilitating non-radiative recombination of charge carriers injectable into the active layer, and an electrode arranged at least on a sidewall of the active layer, wherein the electrode includes a dielectric layer covering the surface states and a conductive material on the dielectric layer, wherein the electrode is configured, based on applying a voltage to the conductive material, to bend a semiconductor band and vary a non-radiative recombination rate, and wherein the conductive material of the electrode extends over the active layer and an adjacent portion.

### CROSS-REFERENCE TO RELATED APPLICATIONS

This patent application is a national phase filing under section 371 of PCT/EP2024/064310, filed May 23, 2024, which claims the priority of German patent application no. 10 2023 113 574.0, filed May 24, 2023, each of which is incorporated herein by reference in its entirety.

### BACKGROUND

Optical data communication becomes an increasingly interested field not only to transmit information over large distances, but also between hardware modules relatively closely arranged to each other with distances of only a few 10 cm to appr. 10 m. Apart from such new applications, optical data communication as such is still a growing market with new and updated requirements in switching time to increase to data transmission speed.

Consequently, the light output of emitters required a high to very high modulation speed in the range of GHz to meet the necessary requirements. More relaxed requirements are found in display applications with its pulse width modulation, although the modulation speed increases here as well into the range of several 10 s to hundreds of KHz. Due to bandwidth requirements, lasers have been most often the emitter of choice. VCSELS as well as edge emitting lasers offer high switching speeds with a relatively narrow bandwidth at reasonable power consumption.

However, light emitters tend to become smaller in size with a length in the range of less than 100 μm. This proves to become a design challenge for lasers as mentioned above. Moreover the current consumption in lasers tend to be higher than those of normal light emitting diodes at the same illumination output with thermal loss and heating becoming an issue. Hence, light emitting diodes have been proposed to replace lasers due to its smaller footprint and reduce power consumption requiring less cooling than lasers.

Still, a large drawback of LEDs relates to their switching speed. The switching speed is mainly limited by the respective ON- and OFF time, also referred to as rise and fall time. While lasers reach several 100 MHz to GHz corresponding to increase and decrease times in the range of several tens of ps, conventional lighting diodes are much slower within a few 100 kHz or us in switching speed. The slow switching speed is caused by the carrier lifetime in the active layer, as the charge carriers still populate the active layer even is the power is switched off.

### SUMMARY

Embodiments provide measures to improve the switching speed of light emitting diodes.

Several approaches have been taken to improve the switching speed. Those were mainly directed at reducing the carrier lifetime, for instance by deliberately introducing impurities into the active layer. Those impurities act as non-radiative recombination centres. As the overall carrier lifetime is a combination of radiative recombination and non-radiative recombination, one can increase one recombination (here the non-radiative recombination) path at the cost of the other. This will, on the one hand, practically shorten the “afterglow” of light after switching off the lighting diode thereby reducing the OFF-switching time. A shorter carrier lifetime may also bring a faster ON-switching, due to the increased rate of carrier density build up in the active layer. However, shortening the carrier lifetime by increasing the non-radiative recombination rate comes with a reduction in the internal quantum efficiency (IQE) and hence an overall efficiency loss.

An alternative approach is the design of an elaborative driving schemes including current spikes at the start of the pulse or reverse biases to speed up the light decay. Usually this requires a complex driver design requiring a larger footprint and driving the costs.

The inventors now propose a third approach, namely, to dynamically control the non-radiative recombination at the sidewalls of a mesa etched optoelectronic device by applying an electrical potential. Mesa etched sidewalls of optoelectronic devices comprise a plurality of surface states, which are usually defect states that cause non-radiative recombination of charge carriers, thereby reducing the overall internal quantum efficiency of the device. In conventional devices the amount of such surface states is usually reduced and minimized by a proper postprocessing after mesa etching (e.g., by passivation with a dielectric layer). The inventors now propose to cover the sidewall with an electrode that can be used to bend the semiconductor bands at the etched mesa sidewalls via an applied potential. This applied potential can have two different effects.

In materials with fast non-radiative surface recombination, for example for certain optoelectronic devices based on phosphide materials, the bending of the bands by an applied potential causes a depletion of one charge carrier type (depending on the polarity of the applied potential), thus reducing or practically cancelling the surface recombination. Consequently, tuning of such potential allows to increase or reduce (even de facto “turn-off”) the non-radiative recombination at the surface. The resulting change in the carrier lifetime can be used to increase or decrease the rising and falling time when switching the optoelectronic device or modulating the light emission thereof.

This will not only allow to reduce the overall switching time, but also individually and separately control the ON-and OFF-time that is the rising and falling edge of a pulse modulated optoelectronic device. Also, this approach could avoid efficiency losses by “turning-off” non-radiative surface recombination during the ON-state of the diode.

In a second concept, which can be used for optoelectronic devices based on the phosphide as well, but also for other material systems, a bending of the band by applying a respective potential through an electrode can be used to flood the interface at the sidewall with one charge carrier type, thus creating a leakage path that can carry a significant current. The bending of the bandgap at the interface due to the potential act as a quasi-ohmic path. And causes a depopulation of the active layer significantly faster than normal radiative recombination, thus leading to a significantly faster switching time.

By selectively activating an additional current conduction mechanism as proposed by the present application, the above-mentioned concepts allow for speeding up the turning ON and turning OFF-time of an optoelectronic device and thus decreased rising and falling edges of the emitted light pulses. This will provide a compact low cost and efficient light source capable of fast switching operation. The implementation using a mesa etched sidewalls is similar for both concepts and can be applied to by a variety of materials systems such as phosphides, arsenides, nitrides, and others.

In some embodiments, the inventors propose an optoelectronic device comprising a mesa etched layer stack. The mesa etched layer stack includes a first layer doped with a first doping type, for example a p-doped layer. The layer stack further comprises a second layer doped with a second doping type, for example, an n-doped layer. The mesa etched layer stack according to the proposed principle also comprises an active layer arranged between the first doped and second doped layer.

The two differently doped layers may comprise one or more sub-layers with different doping concentration or doping profiles. The various sub-layers may provide different functionalities, including but not limited to, current distribution and current transportation. The different doping profiles and doping concentrations can be used to enable a fast transportation and injection of the charge carriers into the active layer. In this regard, the active layer comprises at least one quantum well, but can include also a multi-quantum-well structure having a plurality of alternating barrier and quantum well layers, respectively. Alternatively, the active region may comprise a bulk layer.

The mesa etched sidewalls of the active layer now comprise a plurality of surface states facilitating non-radiative recombination of charge carriers introduced into the active layer. The plurality of surface states is located at the mesa etched sidewalls of the active layer, either directly adjacent to it or close to the sidewalls. However, in accordance with the proposed principle, the non-radiative recombination rate at the surface can be varied and adjusted by tuning the electron and hole densities. This will in turn change the affective carrier lifetime. As a result, the change of the surface recombination rate is used to influence the rising and falling edges of light pulses and thus quickly switch ON or OFF or modulated the light emission of the optoelectronic device.

For this purpose, the optoelectronic device also comprises an electrode, which is arranged at least on the sidewalls of the active layer. The electrode comprises a dielectric layer (or a stack of different layers) covering the sidewalls of the active layer and more particularly, a significant portion of the etched surface. A conductive material is arranged at least some portions of the dielectric layer stack. The electrode is configured to change the non-radiative recombination rate upon applying a voltage to the conductive material.

Depending on the design choice, at least one of the above-mentioned concepts is implemented. This flexibility allows optimizing the rising and falling edges of light pulses emitted by the optoelectronic device. Apart from pure switching as in pulse width modulation applications, the modulation speed as in an amplitude modulation can also be increased in accordance with the proposed principle.

The proposed idea of dynamically modulating an additional current path at the mesa surface can be applied to large and small signal modulation that is said to completely switch ON or OFF the optoelectronic device, but also to simply modulate the optoelectronic device in its light emission or luminosity. The idea can also be applied to different chip concepts including thin film or μ-LEDs.

In this regard, the expression mesa etched optoelectronic device includes an optoelectronic device with a stack comprising sidewalls having a cuboid form, a cylindric form, cone truncated or the form of a truncated pyramid. The sidewalls can either be perpendicular towards a base laser, but also included with regard to a normal axis. The inclination may depend on the etching method and its parameters as well as on the crystal parameters.

The layer stack of the optoelectronic device comprising differently doped layers with a multi-quantum well structure in between is deposited on a growth surface using epitaxial growth processes for example. After the deposition of the layer stack, a respective structured hard mask layer is provided, and one or more etching steps are performed to etch the pixel facets and sidewalls out of the layer stack. The etched pixel facets can then be passivated or otherwise processed and particularly covered with a dielectric material forming a portion of the electrode.

In this regard, the dielectric material of the electrode can either be deposited directly onto the exposed sidewalls after the mesa etching process. Alternatively, a semiconductor layer can be regrown on the sidewalls, whereas the dielectric layer then covers the regrown layer. it is also possible to process the sidewalls after the mesa etching process to influence the density of surface states. This can be achieved by for instance several curing and healing steps to minimize the amount surface states and then subsequently adding a defined amount back onto the sidewalls. Such process is beneficial as it leads to a defined density of surface states and an improved predictability. It may also offer more flexibility in certain material system, for which a mesa etching process does not cause a high density of surface states facilitating non-radiative recombination.

The dielectric layer is made as thin as possible having a range of less than 100 nm and particularly between 20 nm to 80 nm. A highly conductive layer, for example, a metal can then be arranged on the dielectric layer. In some embodiments the metal is gold, silver or another highly reflective material. Depending on the geometry, the reflective layer improves the light emission. The highly conductive material is accessible to apply a potential thereto.

In some embodiments, the active layer comprises at least one cladding layer, in particular an undoped cladding layer. In some embodiments, an undoped cladding layer is arranged between the quantum-well or multi-quantum well structure and each of the doped layers of the layer stack. The undoped cladding layer usually prevents a diffusion of dopants from the first and second doped layers into the multi-quantum well structure of the active layer.

In a further embodiment, the mesa etched sidewalls of the active layer are covered by a regrown layer, on which the electrode is arranged upon. In some embodiments, the bandgap of the regrown layer is larger than a bandgap of the at least one quantum well of the active layer. Furthermore, the bandgap of the regrown layer may also be smaller than bandgap of the at least one cladding layer.

In this regard, it might be useful to electrically couple the conductive material of the electrode to at least one of the first and second layer. This can be achieved using a switch or similar means. In some embodiments, the electrode can be switched between the potential applied to the first layer and the potential applied to the second layer. In other words, the electrode can be switched to the potential of the anode is the cathode during operation of the device. By proper design of the interface between the active layer and the electrode, the applied potential facilitates a band bending, thus reducing or increasing the non-radiative recombination.

To further improve the switching speed, one has to take into account the capacitance of the electrode. One factor dictating this capacitance is the area of the conductive material forming the electrode applied onto the sidewalls. To minimize said parasitic capacitance, the overall area of the electrode covering the sidewall can be reduced. For example, the electrode is located in some instances only on the etched surface of the active layer and optionally the adjacent portions thereof. In some other embodiments, only the conductive material of the electrode is located over the etched surface of the active layer optionally the adjacent portions thereof. Consequently, the conductive material of the electrode may extend only over the active layer. As an alternative, the conductive material of the electrode may extend over the active layer and an adjacent portion of one of the first and second layers, wherein said portion of one of the first and second layer being covered by the conductive material of the electrode is less than 15% of the first and/or second layer respective width. Hence, the electrode does not cover the whole sidewalls of the mesa etched layer stack, but only a portion adjacent to the active layer.

In some embodiments, the dielectric layer of the electrode comprises one of silicon nitride (SiNx), silicon oxide (SiO2) with a thickness of less than 100 nm. The conductive material of the electrode may comprise a metal and in particular gold. Alternatively, another highly reflective metal like silver can be used.

The proposed concept is not limited to a particular type of optoelectronic device or base material system but can a rather flexible be integrated into various designs and material systems. In some embodiments a material of the active layer, and in particular the at least one quantum well can be a based on a phosphide material system like InP, GaP, AlP, GaInP, GaAIP, InAIP, InGaAP, but also arsenide systems like GaAs, AlGaAs. In addition, nitride-based material systems like GaN, InGaN, InAlGaN AIN, InAIN, AlGaN and the like can be used.

Some further embodiments relate to a method of processing an optoelectronic device in accordance with the proposed principle.

For this purpose, a layer stack is provided on a growth substrate and a plurality of further layers doped and undoped are deposited thereupon. Depending on the base material, different kinds of growth substrates including certain buffer layers can be used. The layer stack finally comprises a first layer doped with a first doping type, a second layer doped with a second doping type and an active layer arranged between the first doped and the second doped layer.

The doped layers may comprise a plurality of sub-layers either with different doping concentrations and/or different doping profiles, respectively. The active layer comprises at least one quantum well and may for example contain a quantum well or a multi-quantum well structure. To initiate a mesa containing optoelectronic device, a structured hard mask is applied on the layer stack and one or more mesa etching steps are conducted to define the mesa facets at least along the active layer of the layer stack. The mesa facets of the active layer comprise a plurality of surface states facilitating non-radiative recombination of charge carriers induced into the active layer.

An electrode is then deposited at least on the sidewall of the active layer, wherein the electrode layer comprises a dielectric layer covering the surface states as well as a conductive material arranged on the dielectric layer. The resulting structure enables a band bending when a voltage or potential is applied to the conductive material. The band bending changes the carrier densities at the mesa sidewall, thereby influencing the radiative and the non-radiative recombination ratio. Accordingly, by changing the non-radiative recombination, the carrier density in the active region within the active layer can be injected or depleted significantly faster, thereby reducing the falling or rising edge of a light pulse emitted by the device.

The mesa etching step usually provides a plurality of surface states, although the density of states is random and somewhat unpredictable. Consequently, it is suitable in some embodiments to redefine of the plurality of surface states to provide a defined density of the surface states and particularly a density of surface states in a specific range.

For this purpose, the mesa facets may be cured after the etching process, thereby minimizing the amount of the surface states. This step can be conducted using a wet chemical process, within a gas phase, using an etchant like KOH or by any other suitable means. Then, a plurality of new surface states is re-introduced on the mesa assets of at least the active layer, providing a specific density of such states. Various methods including for instance ion etching and others can be used for this purpose.

A further step in the one or more mesa etching steps may comprise the step of regrowing a semiconductor layer. The regrown semiconductor layer comprises a bandgap that is larger than a bandgap of the quantum well within the active layer, but optionally smaller than a bandgap of a cladding layer.

In some further embodiments, the deposition of an electrode comprises depositing a conductive material on the dielectric layer at a location covering the mesa facets of the active layer but not necessarily extending beyond the mesa facets of the active layer onto the p-doped or n-doped layers. This will ensure that the actual electrode is covering only the portion of the active layer on the sidewalls reducing the parasitic capacitance.

### BRIEF DESCRIPTION OF THE DRAWINGS

Further embodiments in accordance with the proposed principle will become apparent in relation to the various embodiments and examples described in detail in connection with the accompanying drawings in which:

FIG. 1 shows a first embodiment of an optoelectronic device;

FIG. 2 shows a diagram of a band;

FIG. 3 illustrates an equivalent circuit of an optoelectronic device including several current paths corresponding to the different recombination mechanisms;

FIG. 4 illustrates a current-time diagram indicating the simulated switching behaviour and the results thereof;

FIG. 5 illustrates another current-time diagram indicating the simulated switching behaviour and the results thereof;

FIG. 6 shows yet another current-time diagram indicating the simulated switching behaviour and the results thereof;

FIG. 7 illustrates a second embodiment of an optoelectronic device;

FIG. 8 shows a third embodiment of an optoelectronic;

FIG. 9 shows a model for bandgap bending;

FIG. 10 shows current-time diagram indicating the simulated behaviour for the model according to FIG. 9; and

FIG. 11 illustrates a method for operating an optoelectronic device.

### DETAILED DESCRIPTION OF ILLUSTRATIVE EMBODIMENTS

The following embodiments and examples disclose various aspects and their combinations according to the proposed principle. The embodiments and examples are not always to scale. Likewise, different elements can be displayed enlarged or reduced in size to emphasize individual aspects. It goes without saying that the individual aspects, the embodiments and examples shown in the figures can be combined with each other without further ado, without this contradicting the principle according to the invention. Some aspects show a regular structure or form. It should be noted that in practice slight differences and deviations from the ideal form may occur without, however, contradicting the inventive idea.

In addition, the individual figures and aspects are not necessarily shown in the correct size, nor do the proportions between individual elements have to be essentially correct. Some aspects are highlighted by showing them enlarged. However, terms such as “above”, “over”, “below”, “under” “larger”, “smaller” and the like are correctly represented with regard to the elements in the figures. So it is possible to deduce such relations between the elements based on the figures.

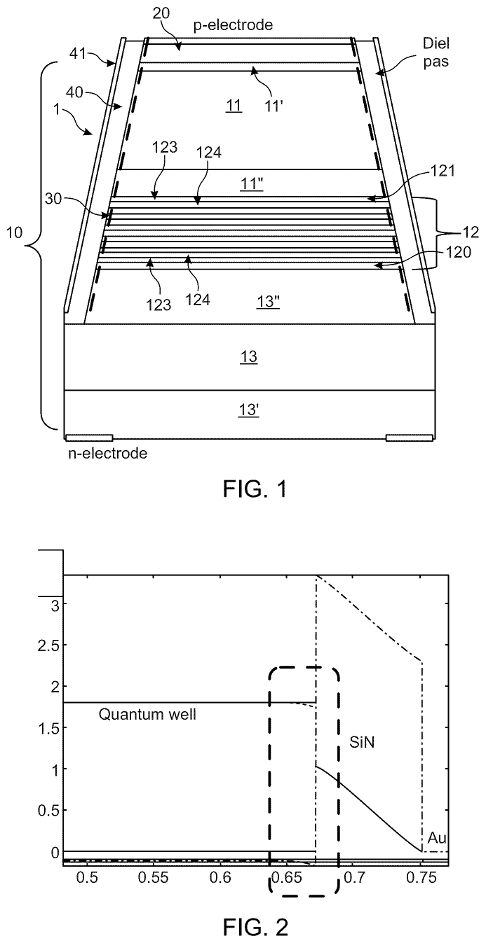

FIG. 1 illustrates an embodiment of an optoelectronic device 1 in accordance with a proposed principle. The optoelectronic device 1 comprises a semiconductor layer stack 10 having a mesa etched sidewall structure forming a vertical u-LED. The layer stack 10 comprises a first n-side electrode made of the conductive metal and second p-side electrode of a reflective conductive layer, reflecting the light to the main emission surface on the other side. The layer stack comprises a plurality of n-doped layers 13, 13′ and 13″. The n-doped layers are deposited on a respective growth substrate (not shown herein) during processing of the optoelectronic device. During processing, a buffer layer of an n-doped material is provided, on which the various n-doped layers 13′, 13 and 13″ are deposited upon. The thickness of the n-doped layers is generally the larger than the thickness of the respective p-doped layers 11, 11′ and 11″ due to the generated growth parameter for forming a defect free surface area.

The dopant concentration in the various n-doped layers 13′, 13 and 13″ varies and depends on the desired functionality. For example, in the present case, the conductive n-electrode is applied on to a highly n-doped layer 13′ for current distribution and charge carrier injection into a subsequently deposited transportation layer 13. The top surface of the transportation layer 13 also forms the bottom of mesa etched surface of the device and is covered on its top surface by material of a dielectric layer 41 forming a portion of the electrode. Another n-doped layer 13″ is arranged on the current transportation layer 13 having a similar, yet different doping concentration including optionally a doping profile to inject the carrier into the active layer 12.

Active layer 12 comprises a very thin undoped cladding layer 120 that further comprises a different bandgap compared to its adjacent layers. The thin cladding layer 120 is used to prevent a diffusion of dopants of layer 13″ into the active layer 12. Active layer 12 further comprises a multi-quantum well structure of a plurality of alternating quantum well layers 123 and quantum barrier layers 124. The quantum well layers 123 generally comprise a smaller bandgap in comparison to the respective barrier layers. In some instances, the quantum well and barrier layers contain a semiconductor material including Al. Different al content then provide the necessary bandgap difference between the barrier and quantum well layers.

Both layers are usually undoped but may also contain a small doping of Si or other dopants to improve the carrier injection, transportation or radiative recombination. Active layer 12 comprises another undoped cladding layer 121 adjacent to the p-doped layer stack 11′, 11 and 11″. Similar to the n-doped layer structure, the p-doped layer structure comprises various sublayers of different doping concentrations and/or different dopant profiles. The various sub layers include a carrier transportation layer 11 and 11″ as well as a current area distribution layer 11′. A conductive layer 20, for example of highly doped semiconductor is deposited adjacent to the layer 11′. A p-electrode made of a transparent conductive material like TCO and the like is arranged upon. The layer stack shown in FIG. 1 is of illustrated purposes only and can be adjusted based on the desired emission wavelength, the operating parameters and other characteristics.

As illustrated in FIG. 1, the optoelectronic device comprises a mesa etched structure with inclined sidewalls reaching from the p-electrode all the way down to the top surface of the n-doped layer 13. During the mesa etching process, a plurality of different surface states is generated along the sidewalls and particularly along and partially within the active layer 12. These surface states usually originate from different kinds of defects, dangling bonds, crystal mismatches or small steps and other resulting in energy states within the bandgap of the multi-quantum well structure and particularly within the bandgap provided by the quantum well layers 123. The surface states within the bandgap act as trap for the charge carriers causing mainly non-radiative recombination during operation of the device. An amount of surface states per surface area correspond to a density of surface states. The density is usually a design or processing parameter and depending on the etching steps and its parameters; however the density of state can be adjusted and should be set to a defined range to improve predictability for operating the device.

The inventors now propose to control the non-radiative recombination caused by these states by actively bending the conduction and valence bands of the active layer close to the surface using an electrode having a dielectric layer 14 and the conductive metal layer 41 deposited upon. In the embodiment of FIG. 1, the sidewalls of the optoelectronic device are covered with a dielectric layer 40 from the top surface of layer 13 all the way to the p-electrode. The material of the dielectric layer comprises for example SiO2 or SiNx. The dielectric material 40 is usually transparent in regard to the light being generated within the active layer. to improve the emission towards the main emission surface (in case a top emitter is required), a reflective and conductive material 41 is deposited on the dielectric material.

The dielectric material 40 covers the surface states of the active layer, preserving a base density of such surface states. The thickness of the dielectric material, for example is in the range between 20 nm to 80 nm. The thickness is one of the possible parameters that will determine the amount of the band bending at the surface of for a given voltage applied to the conductive material.

FIG. 2 in this regard, illustrates a model of the bandgap of the quantum well layer close to the dielectric material with a subsequent gold layer as a conductive material attached on the dielectric material. More particularly, FIG. 2 presents a horizontal cut of the band profile at the given interface of an optoelectronic device based on InAlGaP, on which silicon nitride SiNx as dielectric material and gold as conductive material layer have been the deposited. The conductive gold material is fixed to the potential of the n-contact for example, the ground potential. This results in the illustrated band bending given by the slightly bend line around the dashed area at the interface between the quantum well and the dielectric material.

Although the bending seems to be small in the model, it is adjustable by applying a respective larger or smaller potential to the conductive material deposited on the dielectric material. FIG. 2 provides an example, wherein many more possible choices for a dielectric material, the thickness thereof and other parameters can be made to adjust the band bending at the interface between the quantum well and the dielectric material. The latter together with the surface recombination velocity at the mesa etch influences, which voltage is required in a certain electrode to achieve the desired goal.

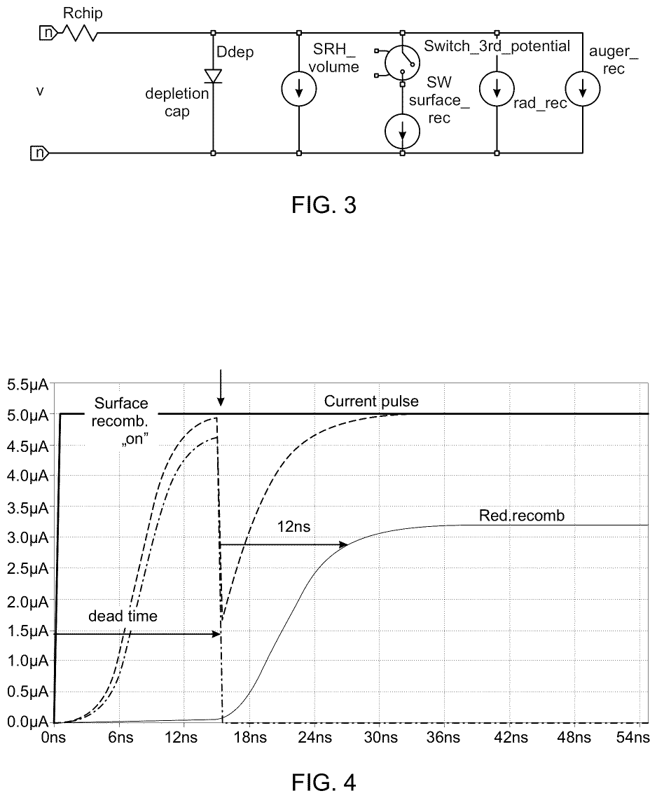

FIG. 3 shows an equivalent circuit picture of the device to provide a more in-depth understanding of the different recombination processes. FIG. 3 comprises a simple scheme, in which the various recombination mechanisms are presented by ideal voltage-dependent current sources, whose respective current level indicate the respective fraction of the recombination mechanism.

The first mechanism SRH_volume is a non-radiative recombination mechanism in the bulk material of the active layer referred to as Shockley-Read-Hall recombination. This portion is dominant at low current densities and in larger optoelectronic devices but its contribution becomes smaller with decreasing device size to the benefit of the second recombination mechanism. This mechanism is the non-radiative recombination caused by surface states, referred to as surface_rec. This recombination mechanism is substantially caused by defects at the mesa facets of the optoelectronic device and leads to an effective lifetime reduction of the charge carriers during operation. The third mechanism is the radiative recombination rad_rec and the last mechanism is an Auger recombination process auger_rec, which is also a non-radiative.

On the one hand, the overall carrier lifetime is given by the combined effect of all these recombination mechanisms. In smaller devices, the contribution of surface recombination can become dominant and effectively dictate the carrier lifetime, the key factor being the ratio of the exposed surface of the active layer to its volume. On the other hand, the amount of emitted light depends on the ratio between radiative recombination and all non-radiative recombination processes. Therefore, in small devices, a very high surface recombination rate can be used to reduce the carrier lifetime significantly and to decrease the emitted light intensity.

Spice simulations have been conducted with the equivalent circuit in FIG. 3 for the purpose of illustration of the various effects and the proposed principle. Typical recombination parameters of the AlGaInP material system have been used to define the voltage dependent current sources. In the simulation, the surface recombination can be dynamically switched at least between ON and OFF and more generally modulated between these two extremes. Such modulation or switching changes the ratio between radiative recombination and non-radiative recombination in response to the modulation of the surface recombination.

FIG. 4 illustrates the simulation results in a time current diagram for a given current pulse, which is switched from it OFF state to it ON state at time o. In the absence of nonradiative surface recombination, it takes about 16.6 ns (not shown here) before the radiative recombination is sufficiently large (90% of the final level). This is the time it takes for sufficient carrier density to build up inside the active region.

In the diagram of FIG. 4, the surface recombination is switched on at t=0, which results in a significant amount of non-radiative recombination, a shorted carrier lifetime and hence a faster build-up of the carrier density. The charge carriers provided by the current pulse at t=0 are recombining at the surface state without any significant amount of light being emitted. Hence, during this dead time period starting at approximately o ns to about 15 ns, the surface recombination sucks most of the charge carriers preventing them from the radiative recombination.

At about 15 ns, the surface recombination is deactivated by applying a respective third potential. As a result, the radiative recombination now starts to increase significantly but also rather quickly. The quick raise is supported by the already populated active layer. Compared to conventional solutions, in which no change of the surface recombination takes place, the improvement of speed ranged from about 17 ns to 12 ns. The rising edge of 12 ns is appr. 30% faster than the rising edge in conventional solutions.

As a result, the increase of radiative recombination during the rising edge taking place is significantly faster compared to conventional solutions, thereby reducing the switching ON time. In addition, reducing the density of the surface states by applying a proper potential improve the internal quantum efficiency, thereby increasing the overall illumination output while preserving the total amount of power being consumed. Nevertheless, as also illustrated in FIG. 4, a potential downside of the faster rising edge of the light pulse is the dead time in the beginning due to the activated surface recombination. However, this time is known and can be compensated by properly designing the switching ON and OFF signals.

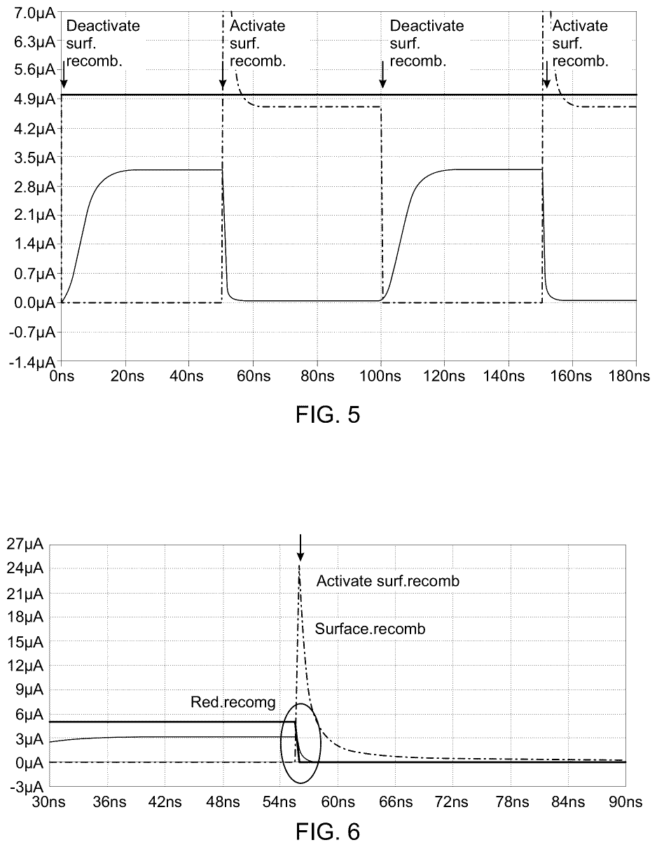

FIG. 5 in this regard, illustrates another simulation example, in which the current through the optoelectronic device is always active and the modulation of the light output is solely performed through the application of the respective third potential. As illustrated in FIG. 5, the current pulse is continuously activated with approximately 5 μA all the time and the surface recombination periodically activated and deactivated, respectively to create pulses approximately every 50 ns. The example shown corresponds to large signal modulation, but the same idea could be applied to obtain small signal modulation.

Consequently, the rising edge of each pulse is approximately 10 ns to 12 ns with the falling etch even faster within the range of 1 ns to 2 ns. An embodiment, in which the optoelectronic device is continuously supplied with a certain DC current and directly switched or modulated by applying a third potential at an electrode to vary the surface recombination rate provides a fast rising and falling edge of the respective pulses or a fast amplitude modulation, respectively. The continuous supply current through the optoelectronic device allows for a simpler driver design option, but also causes a higher overall power consumption. In an alternative embodiment, one can switch on the current through the device slightly prior to deactivating the surface recombination to ensure a fast edge rising time. When the optoelectronic device is switched OFF by surface recombination activation (e.g. at approx. 50 ns or 150 ns in the diagram), the overall DC current through the device can also be switched OFF shortly after the surface recombination has been activated. This will reduce the current consumption to acceptable levels without compromising switching time or increasing the heat generated by the device.

The behaviour of activating the surface recombination to decrease the time for the falling edge of light pulse is also illustrated in FIG. 6. The activated surface recombination at the end of the pulse significantly increases the non-radiative recombination, thereby very quickly depopulating the active layer, resulting in a large reduction of the light decay time. At the same time, the DC current pulse is also set to o, so the activation of the surface recombination can be switched off as well shortly thereafter.

The presented concepts can be modified and vary depending on the base material system and the physical characteristics thereof including, for example, the overall carrier lifetime, the diffusion length and other parameters. The potential for a very fast switching OFF and thereby a very short falling edge seems to be attractive for the proposed concept. The switching ON time reduction as illustrated above is useful if a small additional DC a current consumption can be accepted, or the additional dead time compensated in the modulation of the device.

Another embodiment related to the switching speed is given by the capacitance of the electrode arranged on the sidewalls of the optoelectronic device. Applying a potential on the electrode nevertheless requires certain charge carriers to be added or subtracted from the respective electrode. Accordingly, the electrode together with the dielectric material creates a certain parasitic capacitance, which needs to be charged or discharged to switch the non-radiative recombination. Consequently, this parasitic capacitance should be minimized to avoid a delay in the switching speed. Since most of the surface recombination occurs at the mesa facets of the active layer, the inventors propose to limit the location of the respective electrode to the sidewalls of the active layer.

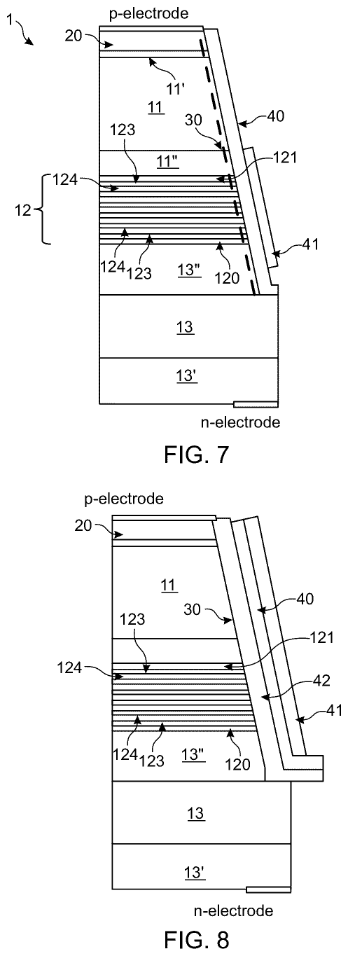

FIG. 7 illustrates an exemplary embodiment of an optoelectronic device, on which the electrode is substantially located adjacent to active layer 12. Same elements in the optoelectronic device are usually bearing the same reference numerals.

In the present embodiment, the optoelectronic device comprises an electrode having a dielectric material 40 and a conductive material 41. While the dielectric material 40 is substantially arranged over the whole sidewalls covering the various surface states 30 of the active layer and the doped layers, the conductive material 41 is supplied only over the area corresponding to the sidewall of the active layer 12 as well as the cladding layers 121 and 120, respectively. In some instances, the conductive material 41 of the third electrode may also slightly extend on the leading layers of active layer 12 into the p-and n-doped layer without completing covering the sidewall of those layers. The reduced size of the electrode material 41 reduces the parasitic capacitance associated with the electrode allowing for far faster change of capacitance and thereby a faster switching or modulation of the radiative recombination.

FIG. 8 illustrates another embodiment of the proposed principle concerning a concept referred to as channel leakage concept. After structuring and etching the layer stacks forming the inclined sidewalls. As illustrated in FIG. 8, a thin semiconductor layer 42 can be re-grown on the respective sidewalls of the regrowth.

The regrown semiconductor layer 42 comprises a thickness in the range of a few 10 nm to hundred nanometres and a bandgap that is larger than the bandgap of the active layer and the multi-quantum well structure therein, particularly larger than the bandgap of the respective multi-quantum wells. However, the bandgap of the regrown semiconductor layer 42 could be lower than the bandgap of the respective cladding layers 120 and 121, respectively. This would lower the turn-on voltage of the leakage channel compared to that of the active region, thus requiring a lower potential in the third electrode to open the leakage channel. The dielectric material 40 of the electrode as well as a conductive layer material 41 in form of a conductive metal are then deposited to form the electrode on the sidewall of the mesa etched layer stack.

In some embodiments, the potential bending of the bandgap is large enough to cause the formation of a channel along the multi-quantum well structure, thereby creating a leakage path that can carry a significant current of one carrier type. The leakage channel created by the band bending acts as a quasi-ohmic path and will significantly reduce the falling edge time of light pulses emitted by the optoelectronic device by sweeping the charge carrier of one type out of the active layer.

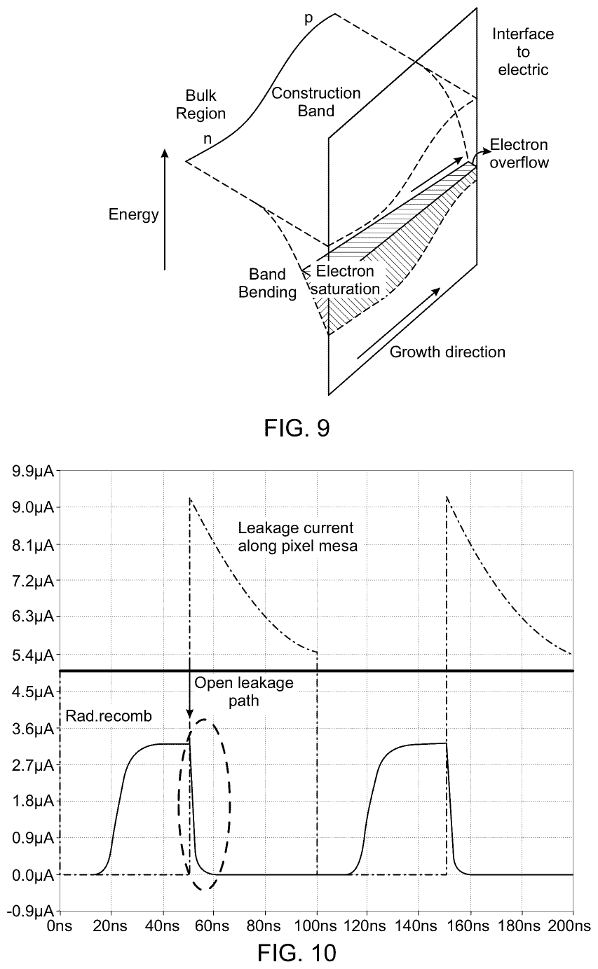

FIG. 9 illustrates the passage created at the interface between the multi-quantum well structure and the dielectric material of the electrode. As illustrated due to the band bending caused by the applied voltage, an electron (or more generally a charge carrier) path is created at the interface similar to the channel of a field effect transistor between the n-doped portion and the p-doped portion through the multi-quantum well structure of the device. This causes the charge carriers to overflow into the doped area without recombining in the active layer or emitting light.

The result of such leakage current along the interface between the active layer and the dielectric of the electrode is illustrated in the simulation of FIG. 10. During operation the DC current is still continuously flowing through the device. At approx. 50 ns the leakage path is created to open the current channel. As a result, the radiative recombination drops significantly within a very short timeframe of a few nanoseconds. The extra current path parallel to the active layer corresponds to a parallel quasi-ohmic path where no radiative recombination takes place. If the resistance of the generated leakage path is low enough, the voltage within the active layer drops fast when this channel is opened, and the light decay is accelerated due to quick depletion of charge carriers able to radiatively recombine in the active layer.

The proposed electrode on the sidewalls can now be connected either to a separate third potential or via a switch to one of the n-or p-electrodes. By design of the respective dielectric layer and the choice of the conductive material, it is possible to get a flat band condition at the surface of the active layer, which corresponds to the maximum of the non-radiative recombination mechanism when connected to one of the above-mentioned electrodes. As a result, when switching to the other electrode, band bending of the bandgap at the surface of the active layer increases and the non-radiative recombination is reduced. This allows modulating the ON and OFF ratio of the non-radiative recombination.

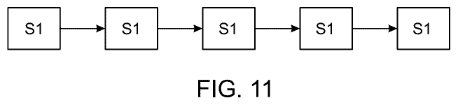

FIG. 11 illustrates a method for processing an optoelectronic device. In step Si a growth substrate is provided having a buffer layer deposited thereupon to provide a smooth and substantially defect free surface. Buffer layer and growth substrate are adjusted to comply with the growth requirements of the material system of the optoelectronic device and the layer stack deposited upon.

A plurality of differently doped layers is then deposited, wherein the doping concentration and doping profile is adjusted to provide a dedicated functionality. In particular, one or more first layers doped with a first doping type of varying concentrations are deposited. Then, a small and thin cladding layer being part of an active layer is deposited on the uppermost layer with the first doping type. The cladding layer is used to prevent diffusion of dopants into the active region.

Then, a plurality of alternating quantum well and quantum the barrier layers are deposited. The bandgap of the quantum barrier layers is slightly larger than the bandgap of the quantum well layers, which can for example be achieved by slightly changing the composition of the base material system. The numbers of quantum well and quantum barrier layers, respectively can vary and may range from 2 to approximately 30 different layers. Another undoped cladding layer is deposited on top of the last the quantum well or quantum barrier layer.

In step S2 of the exemplary embodiment, a structured mask on the layer stack is applied. The structured mask is a hard mask layer substantially insensitive towards the next step S3, in which one or more mesa etching steps are conducted. the mesa etching process in step S3 removes material of the layer stack exposed by the structured mask on the layer stack thereby forming mesa facets along the sidewalls of the layer stack. More particularly, mesa facets of the active layer are exposed by the mesa etching steps.

The mesa etching step usually results in a plurality of different surface states facilitating non-radiative recombination of charge carriers when induced into the active layer during operation of the device. To define a density of states in a specific range, the surface of the mesa assets on the active layer is cured and annealed in step S4 to minimize the overall amount of surface states. After curing, a plurality of surface states is re-introduced to define the density of surface states in a determined and desired range.

In a final step S5, an electrode is deposited on the sidewall of the active layer, wherein the electrode comprises a dielectric layer covering the surface states as well as a conductive material on the dielectric layer. The conductive material can be electrically connected to one of the first or second layers in operation of the device, thereby providing a potential equally to the electrical potential applied to one of the contacts of the layer stack. This would avoid the need for an independent potential source for the third contact.

In an alternative embodiment, the mesa assets can be covered by material of a regrowth layer prior to applying the dielectric layer of the electrode.

1.-14. (cancelled)

15. An optoelectronic device comprising:
a mesa etched layer stack comprising:
a first layer doped with a first doping type;
a second layer doped with a second doping type; and
an active layer arranged between the first layer and the second layer, wherein the active layer comprises at least one quantum well,
wherein mesa etched sidewalls at or in an immediate vicinity of the active layer comprise a plurality of surface states configured for facilitating non-radiative recombination of charge carriers injectable into the active layer;
an electrode arranged at least on a sidewall of the active layer, the electrode comprising:
a dielectric layer covering the surface states; and
a conductive material on the dielectric layer,
wherein the electrode is configured, based on applying a voltage to the conductive material, to bend a semiconductor band and vary a non-radiative recombination rate,
wherein the conductive material of the electrode extends over the active layer and an adjacent portion, and
wherein the adjacent portion is less than 15% of a width of one of the first layer or the second layer.

16. The optoelectronic device according to claim 15, wherein active layer comprises at least one cladding layer.

17. The optoelectronic device according to claim 15, wherein mesa-edge sidewalls of the active layer are covered by a regrown layer on which the electrode is arranged.

18. The optoelectronic device according to claim 17, wherein a bandgap of the regrown layer is larger than a bandgap of the at least one quantum well of the active layer, and optionally smaller than a bandgap of the at least one cladding layer.

19. The optoelectronic device according to claim 15, wherein the conductive material of the electrode is electrically connected to at least of the first layer or the second layer.

20. The optoelectronic device according to claim 15,
wherein the dielectric layer of the electrode comprises one of SiNx or SiO2, and/or
wherein the conductive material of the electrode comprises a metal.

21. The optoelectronic device according to claim 15, wherein the dielectric layer of the electrode is less than 100 nm.

22. The optoelectronic device according to claim 15, wherein a material of the active layer is based on InP, GaP, AlP, AlGaP, InGaP, AlGaInP, GaAs, or AlGaAs.

23. A method of processing an optoelectronic device, the method comprising:
providing a layer stack comprising a first layer doped with a first doping type, a second layer doped with a second doping type, and an active layer arranged between the first layer and the second layer, wherein the active layer comprises at least a quantum well;
applying a structured mask on the layer stack;
mesa etching to define mesa facets at least along the active layer of the layer stack, wherein the mesa facets of the active layer comprise a plurality of surface states configured for facilitating non-radiative recombination of charge carriers inducible into the active layer; and
depositing an electrode layer at least on a sidewall of the active layer, the electrode layer comprising a dielectric layer covering the surface states and a conductive material on the dielectric layer, wherein the conductive material of the electrode layer extends over the active layer and an adjacent portion, and wherein the adjacent portion is less than 15% of a width of one of the first layer or the second layer.

24. The method according to claim 23, mesa etching comprises re-defining the plurality of surface states to provide a density of surface states in a specific range.

25. The method according to claim 24, further comprising:
curing the mesa facets thereby minimizing an amount of the surface states; and
re-introducing surface states on the mesa facets of at least the active layer.

26. The method according to claim 23, mesa etching comprises regrowing a semiconductor layer, wherein the semiconductor layer comprises a bandgap larger than a bandgap of the quantum well within the active layer.

27. The method according to claim 23, wherein depositing the electrode layer comprises depositing the conductive material covering substantially only the mesa facets of the active layer.
